(19) United States
(12) Patent Application Publication
(10) Pub. No.: US 2006/0081961 A1
(43) Pub. Date: Apr. 20, 2006

(54) Variable resistance device and a semiconductor apparatus, including a variable resistance layer made of a material with a perovskite structure

(75) Inventors: Keisuke Tanaka, Ibaraki-shi (JP); Yoshihisa Kato, Otsu-shi (JP); Zhiqiang Wei, Ibaraki-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/231,744

(22) Filed: Sep. 22, 2005

(30) Foreign Application Priority Data
Oct. 19, 2004 (JP) 2004-304461

(51) Int. Cl. H01L 29/00

(52) U.S. Cl. 257/536; 257/379; 257/537

(57) ABSTRACT

The present invention offers a variable resistance device and a semiconductor apparatus that have component parts less subject to damage and thereby ensure stable quality at a high yield, even if the manufacturing processes include operations in a deoxidizing atmosphere or an oxidizing atmosphere. The variable resistance device of the present invention comprises: a variable resistance layer made of a metal oxide and causing changes in electric resistance thereof in accordance with control conditions; and a hydrogen-diffusion preventing layer which surrounds at least part of the variable resistance layer and prevents hydrogen from diffusing into the variable resistance layer.

### BACKGROUND OF THE INVENTION

1. Field of the Invention

The present invention relates to a variable resistance device and a semiconductor apparatus, in particular to the structure of the variable resistance device including a variable resistance layer made of a material with a perovskite structure.

2. Related Art

Nonvolatile memories, in which stored data will not be lost even if a power supply is off, have undergone an explosive expansion in step with the development of mobile devices, such as digital still cameras and portable phones. Flash memories that accumulate charges on the floating gates of transistors have become the mainstream of conventional nonvolatile memories. However, it is difficult to scale tunnel oxide films forming the floating gates of flash memories while maintaining the nonvolatility, and therefore, next-generation nonvolatile memories have been awaited.

In response to such demand, it has recently been proposed to construct a memory device with a variable resistance portion using a thin film that exhibits change in the electric resistance in accordance with an electric field change caused by application of a voltage pulse—that is, Resistance Random Access Memory, or RRAM (e.g. refer to the U.S. Pat. Publication No. 6,204,139; and International Electron Device Meeting Technical Digest, 2002, p. 193). Such a memory device has attracted attention as a nonvolatile memory enabling microfabrication, and has been expected as a prospective device replacing flash memories.

A structure and operation of a RRAM using a variable resistance device discussed in these references are explained next, with reference to FIG. 1. FIG. 1 is a schematic cross section showing a structure of the RRAM.

In the RRAM, n-type impurity-diffused portions are formed within a p-type silicon substrate 140, extending inwardly in the thickness direction from the surface thereof, and herewith, a source electrode 141a and a drain electrode 141b are formed, as shown in FIG. 1. Then, a gate insulating layer 142 and a gate electrode 143 are successively stacked in layers on part of the surface of the p-type silicon substrate 140, located between the source and drain electrodes 141a and 141b. In the RRAM, these portions—that is, the source and drain electrodes 141a and 141b, the gate insulating layer 142, and the gate electrode 143, compose a field effect transistor (referred to hereinafter as the “FET”), and function as a selection switch. On top of the p-type silicon substrate 140 where the FET is formed, an interlayer insulating layer 144 is made by cladding, and a word line 145 and a common line 146 are connected to the gate electrode 143 and the drain electrode 141b, respectively.

Formed on top of the source electrode 141a is an underside electrode 147, on which a variable resistance layer 148 made of Pr_{0.7}Ca₃MnO₃ (referred to hereinafter as “PCMO”)—a colossal magnetoresistive (CMR) material, is deposited. In addition, an upside electrode 149 also functioning as a bit line is laid in a layer on top of the variable resistance layer 148. Here, PCMO constituting the variable resistance layer 148 has a perovskite structure. In the RRAM, the variable resistance layer 148 is normally (i.e. when no pulse is applied) in a low electric resistance state, and the variable resistance layer 148 is brought into a high electric resistance state by applying a write pulse to the bit line while the selection switch is on. Furthermore, a reset pulse is applied to the common line 146 in order to restore the variable resistance layer 148 back to a low electric resistance state.

The resistance ratio between the high and low electric resistance states of the variable resistance layer 148 made of PCMO with a perovskite structure reaches 100 to 1000, and it is possible to correspond data “1” and data “0” to the high and low electric resistance states, respectively.

With the RRAM, in order to read written data, an electric current is applied to the variable resistance layer 148 from the bit line, and the magnitude of a voltage drop corresponding to the electric resistance state of the variable resistance layer 148 is detected by a sense amplifier (not shown in the figure) connected to the bit line. The resistance value of the variable resistance layer 148 induced by the application of a voltage pulse is maintained in a nonvolatile manner until the next pulse is applied.

### SUMMARY OF THE INVENTION

However, a semiconductor apparatus using the above conventional memory device has two problems as follows.

The first problem is that the variable resistance layer 148, a high dielectric constant layer, or the like is deoxidized during the semiconductor manufacturing processes. That is, in the case where a semiconductor apparatus is constructed by using memory devices like described above, both multiple variable resistance members and field effect transistor members (referred to hereinafter as the “FET members”) are arranged in a two dimensional layout, or so-called an array, as disclosed in the U.S. Pat. Publication No. 6,204,139. A metal oxide having a perovskite structure can be used as a constituent material of the variable resistance layer of each variable resistance member, as mentioned above. However, interlayer insulating layers and metal wiring also need to be formed, in addition to the variable resistance layer, in order to integrate the variable resistance members on a semiconductor substrate and to actually make these members operate as an integrated memory device. In regard to the manufacturing processes of a semiconductor apparatus having such a structure, it is sometimes the case that the variable resistance layer made of a metal oxide is deoxidized during a heat treatment conducted in a deoxidizing atmosphere containing hydrogen and hydrogen compounds.

Among the manufacturing processes, a number of processes likely to deoxidize the variable resistance layers exist after the variable resistance members are formed, and any of these processes is indispensable for manufacturing a semiconductor apparatus including the memory devices. Such processes include, for instance: a heat treatment process in an atmosphere containing hydrogen, in a metal wiring operation; a film formation process for forming interlayer layers made of hydrogen compounds; and an ashing process of hydrogen-containing photoresist masks which are used for fabrication of the variable resistance materials, metal wiring and electrodes. When the variable resistance layers of the variable resistance members are deoxidized, the regularity of the crystal structure is lost. Consequently, after the completion of the manufacture of the memory devices, the resistance value of each variable resistance layer does not change even if a voltage pulse is applied.

The second problem is that layers and the like made of variable resistance materials are likely subject to process damage during their formation and fabrication, and therefore, they are generally treated in a high-temperature oxygen atmosphere in order to eliminate such process damage. However, it is sometimes the case that contact plugs and transistor members are oxidized during the treatment. For example, when FET members are formed in the proximity of layers made of variable resistance materials and then the FET members are connected to these variable resistance layers by contact plugs, the contact plugs are made of polysilicon or tungsten in order to lower the contact resistance. In such a case, polysilicon or tungsten used to form the contact plugs is susceptible to oxidation, which may lead to malfunction of a semiconductor apparatus after the completion of the manufacture.

The present invention has been made in order to solve the above problems, and aims at offering a variable resistance device that has component parts less subject to damage and thereby ensures stable quality at a high yield, even if the manufacturing processes of the variable resistance device include operations in a deoxidizing atmosphere or an oxidizing atmosphere. At the same time, the present invention also aims at providing a manufacturing method of the variable resistance device as well as a semiconductor apparatus.

The variable resistance device according to the present invention comprises: a variable resistance layer made of a metal oxide and causing changes in electric resistance thereof in accordance with control conditions; and a hydrogen-diffusion preventing layer which surrounds at least part of the variable resistance layer and prevents hydrogen from diffusing into the variable resistance layer. Herewith, in the variable resistance device of the present invention, the hydrogen-diffusion preventing layer prevents, even in a deoxidizing atmosphere of the semiconductor manufacturing processes, hydrogen in the atmosphere from diffusing into the variable resistance layer, and therefore, the variable resistance layer becomes less likely to be deoxidized. Thus, the variable resistance device of the present invention has the variable resistance layer less subject to damage, which ensures stable quality.

Accordingly, as to the variable resistance device of the present invention, even if the manufacturing processes of the variable resistance device include operations in a deoxidizing atmosphere, the variable resistance layer is free from damage, which allows to ensure stable quality of the variable resistance device at a high yield.

In particular, if the variable resistance device of the present invention adopts a structure in which the hydrogen-diffusion preventing layer surrounds the entire variable resistance layer, it is possible to prevent hydrogen from diffusing into the variable resistance layer from all directions, which provides more reliable protection of the variable resistance layer in a deoxidizing atmosphere. Thus, the variable resistance device according to the present invention further enhances its reliability.

The variable resistance device of the present invention may adopt a structure in which a high dielectric constant layer is inserted between the variable resistance layer and at least one of a plurality of conductive electrodes connected to the variable resistance layer. Herewith, when voltage is applied between the plurality of electrodes positioned across the variable resistance layer, the variable resistance device, after the completion of the manufacture, is capable of lowering a through current flowing between these plurality of electrodes, which allows to lower the power consumption.

The variable resistance device of the present invention may adopt a structure in which the hydrogen-diffusion preventing layer includes a 1st diffusion preventing component and a 2nd diffusion preventing component which are disposed across the variable resistance layer in the thickness direction—that is, disposed on the upper and lower sides of the variable resistance layer of the variable resistance device, and in which the 1st and 2nd diffusion preventing components are made of different materials. Herewith, according to where the 1st and 2nd diffusion preventing components are disposed, constituent materials ideal for the hydrogen-diffusion preventing layer can be selected, which in turn increases flexibility in the design of the variable resistance device. Especially in the case when such a structure is adopted, the 1st diffusion preventing component may be formed from an insulating material. Herewith, it is possible to prevent parasitic capacitance from being created between the variable resistance layer and the 1st diffusion preventing component which is formed to cover the upper side of the variable resistance layer. Alternatively, in the case when multiple variable resistance devices are integrated in close proximity to each other, the 1st diffusion preventing component formed to cover the upper side of these multiple devices is capable of preventing cross talk between the devices positioned next to each other.

Regarding constituent materials of the 1st diffusion preventing component, it is desirable to include at least one compound selected from the group consisting of silicon oxide, silicon oxynitride, silicon nitride, aluminum oxide, titanium aluminum oxide, and tantalum aluminum oxide.

The variable resistance device of the present invention may adopt a structure in which the 2nd diffusion preventing component is made of a conductive material. Herewith, not only can hydrogen diffusion be prevented by the 2nd diffusion preventing component, but also it is possible to apply an electric potential to the variable resistance layer, via the conductive material forming the 2nd diffusion preventing component, from the lower side of the variable resistance layer. Here, if the variable resistance device of the present invention adopts a structure in which part of the variable resistance layer is directly joined to part of the hydrogen-diffusion preventing layer, the manufacturing processes of the variable resistance device according to the present invention can be simplified.

In the variable resistance device of the present invention, an electrode having a function of preventing hydrogen diffusion may be made to also function as the 2nd diffusion preventing component—one of the two diffusion preventing components disposed across the variable resistance layer in the thickness direction so as to surround two main surfaces of the variable resistance layer. Herewith, hydrogen diffusion through the electrode can be prevented, which in turn prevents the deoxidation of the variable resistance layer in a more reliable manner.

The variable resistance device of the present invention may adopt a structure in which a lateral side of the electrode is covered by a lateral-side hydrogen-diffusion preventing layer. This structure increases adhesion between the electrode functioning as the 2nd diffusion preventing component and the hydrogen-diffusion preventing layer surrounding the electrode, which allows to prevent the deoxidation of the variable resistance layer in a further definitive manner.

In the variable resistance device of the present invention, the above electrode may include, along with a hydrogen-diffusion-preventing component layer, an oxygen-diffusion-preventing component layer which has a function of preventing oxygen diffusion. Herewith, not only can the deoxidation of the variable resistance layer be prevented in a reliable manner, but also it is possible to prevent oxidation of the contact plugs and transistors formed on the lower side of the electrode. Additionally, when this electrode structure is adopted, the presence of the hydrogen-diffusion-preventing component layer prevents the function of the oxygen-diffusion-preventing component layer from being degraded due to due to the deoxidation by hydrogen.

Here, the hydrogen-diffusion-preventing component layer in the electrode may be made of a material including at least one compound selected from the group consisting of titanium nitride, titanium aluminum nitride, titanium aluminum, titanium nitride silicide, tantalum nitride, tantalum nitride silicide, tantalum aluminum nitride, and tantalum aluminum.

The oxygen-diffusion-preventing component layer in the electrode may be made by including at least one of the following: iridium oxide; a layered structure in which layers of iridium oxide and iridium are successively stacked in a stated order from a side closest to the variable resistance layer; ruthenium oxide; and a layered structure in which layers of ruthenium oxide and ruthenium are successively stacked in a stated order from the side closest to the variable resistance layer.

The variable resistance device of the present invention may adopt a structure in which an insulating layer is inserted into at least a portion between the variable resistance layer and the hydrogen-diffusion preventing layer. Herewith, in the case where the variable resistance layer has, for example, difference in level on the surface thereof, it is possible to prevent causing a discontinuity in the hydrogen-diffusion preventing layer laid above the variable resistance layer due to the level difference. Especially when the variable resistance device has an insulating layer as is in this case, it is desirable that the insulating layer contain no hydrogen in order to avoid chance of hydrogen diffusion into the variable resistance layer.

As to the variable resistance device of the present invention, it is desirable that the hydrogen-diffusion preventing layer include at least one of the plurality of elements constituting the variable resistance layer. This is because, even if interdiffusion of elements occurs between the variable resistance layer and the hydrogen-diffusion preventing layer, impact exerted on the properties of the variable resistance layer would be reduced.

As to the variable resistance device of the present invention, it is desirable that the hydrogen-diffusion preventing layer include a magnetic element. This is because the variable resistance layer is surrounded by the hydrogen-diffusion preventing layer with the magnetic element, and this magnetic element functions as a magnetic shield, reducing external magnetic field effects on the variable resistance layer.

As to the variable resistance device of the present invention, it is desirable that the variable resistance layer be made of a material having a perovskite structure. Similarly, it is preferable that the high dielectric constant layer be also made of a material having a perovskite structure. Herewith, in the case where the variable resistance layer is made of a material having a perovskite structure, the lattice mismatch between the high dielectric constant layer and the variable resistance layer can be avoided, and therefore stress exerted on the variable resistance layer is prevented, which in turn prevents degradation of the properties of the variable resistance layer.

The variable resistance device of the present invention may adopt a structure in which, from among the plurality of electrodes connected to the variable resistance layer, at least two electrodes are positioned opposite to each other across the variable resistance layer. In this case, with the use of these paired electrodes opposing each other, the electric resistance state of the variable resistance layer can be easily changed by applying voltage to the variable resistance layer.

A semiconductor apparatus according to the present invention comprises a variable resistance device. Here, the variable resistance device includes: a variable resistance layer made of a metal oxide and causing changes in electric resistance thereof in accordance with control conditions; and a hydrogen-diffusion preventing layer which surrounds at least part of the variable resistance layer and prevents hydrogen from diffusing into the variable resistance layer. The semiconductor apparatus of the present invention with such a structure exhibits the same advantageous effects of the above-described variable resistance device of the present invention. That is, even if the manufacturing processes of the semiconductor apparatus of the present invention include operations in a deoxidizing atmosphere, a component having the variable resistance layer is free from damage, which allows to ensure stable quality of the semiconductor apparatus at a high yield.

### BRIEF DESCRIPTION OF THE DRAWINGS

These and other objects, advantages and features of the invention will become apparent from the following description thereof taken in conjunction with the accompanying drawings which illustrate specific embodiments of the invention. In the drawings:

FIG. 1 is a schematic cross section showing a structure of a conventional variable resistance memory device;

FIG. 2 is a schematic cross section showing a structure of a memory device 1 of a semiconductor apparatus according to Embodiment 1;

FIG. 3A is a process drawing showing steps of the manufacturing processes of the memory device 1;

FIG. 3B is another process drawing showing steps of the manufacturing processes of the memory device 1;

FIG. 4A is another process drawing showing steps of the manufacturing processes of the memory device 1;

FIG. 4B is another process drawing showing steps of the manufacturing processes of the memory device 1;

FIG. 5 shows X-ray diffraction profiles of variable resistance layers of variable resistance members according to a practical example and a comparative example, obtained after hydrogen annealing;

FIG. 6 is a characteristic diagram related to the practical example, showing the relation between the resistance ratios of the variable resistance member obtained before and after hydrogen annealing;

FIG. 7 is a characteristic diagram showing contact resistance between contact plugs and barrier electrodes for variable resistance members according to the practical and comparative examples;

FIG. 8A is a schematic cross section (along the line B-B) showing a structure of a memory device 2 of a semiconductor apparatus according to Embodiment 2;

FIG. 8B is a schematic cross section (along the line A-A) showing a structure of the memory device 2; and

FIG. 9 is a schematic cross section showing a structure of a memory device 3 of a semiconductor apparatus according to Embodiment 3.

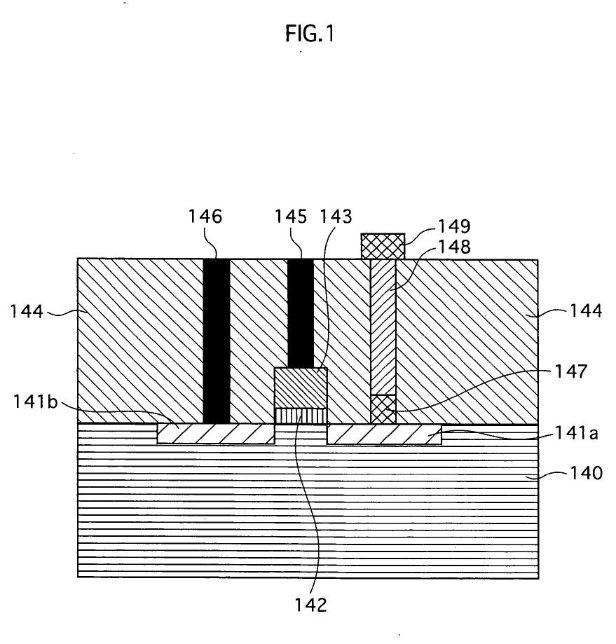

### DESCRIPTION OF PREFERRED EMBODIMENTS

The best modes for implementing the present invention are described next, with the aid of drawings. Note that embodiments and modifications described below are merely examples for illustrating the structures and functions of the present invention, and therefore the present invention is not confined to these.

### 1. Embodiment 1

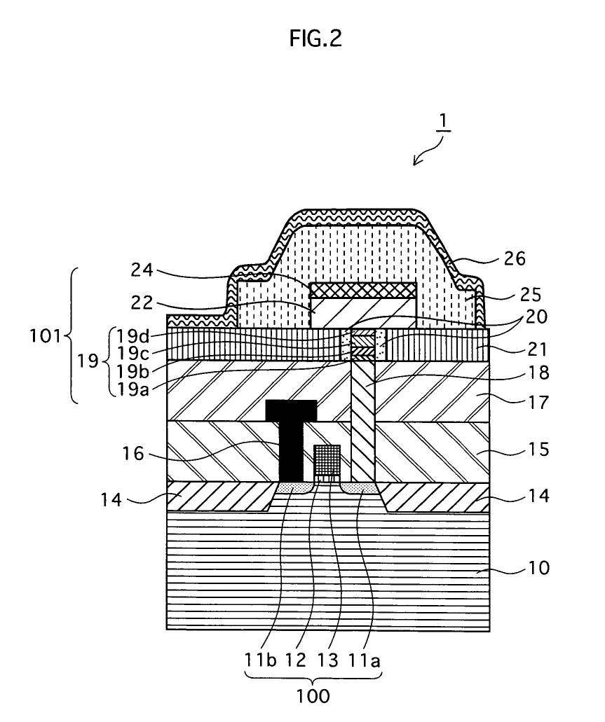

A memory device 1 of a semiconductor apparatus according to Embodiment 1 is described below, with the aid of FIGS. 2 to 6.

### 1.1 Structure of Memory Device 1

The structure of the memory device 1 is described in reference to FIG. 2. FIG. 2 is a schematic cross section showing the structure of the memory device 1 according to the present embodiment.

As shown in FIG. 2, the memory device 1 of the present embodiment has a structure in which, broadly speaking, a variable resistance member (a variable resistance switching unit) 101 and a selection field effect transistor member (referred to hereinafter as the “FET member”) 100 are integrated. Note that, although FIG. 2 depicts one variable resistance member 101 and one FET member 100, the memory device 1 may have a structure where multiple memory cells, each of which comprises a single variable resistance member 101 and a single FET member 100, are integrated.

As shown in FIG. 2, two sections where n-type impurities are diffused—that is, a source electrode 11a and a drain electrode 11b, are formed within a p-type silicon substrate 10, extending inwardly from the surface thereof. Formed on the sides of the source and drain electrodes 11a and 11b are member isolation portions 14. On the surface of the p-type silicon substrate 10 where these layers 11a, 11b and 14 are formed, a 1st interlayer insulating layer 15, a 2nd interlayer insulating layer 17, and a buried insulating layer 21 are successively laid in layers. The 1st and 2nd interlayer insulating layers 15 and 17 are made, for example, of silicon oxide (SiO₂). The buried insulating layer 21 is made of an insulating material, and has a function as a hydrogen barrier for preventing diffusion of hydrogen.

Laid on a part of the surface of the buried insulating layer 21 is a variable resistance layer 22 made of PCMO, which is a material having a perovskite structure, and an upside electrode 24 is laid on top of the variable resistance layer 22. Furthermore, an interlayer insulating layer 25 made of a material containing no hydrogen is laid on the surface of the buried insulating layer 21 in a manner to cover the variable resistance layer 22 and upside electrode 24. Then, an insulating hydrogen barrier layer 26 is formed on the surface of the interlayer insulating layer 25. Here, the interlayer insulating layer 25 is made, for example, of silicon oxide containing no hydrogen (e.g. an ozone TEOS film). The hydrogen barrier layer 26, which is made, for example, of aluminum oxide and is approximately 5 nm to 100 nm in thickness, also has a function of preventing diffusion of hydrogen as with the buried insulating layer 21.

Formed on the upper side of the drain electrode 11b is a metal wiring 16, which penetrates through the 1st interlayer insulating layer 15 and extending to the inside of the 2nd interlayer insulating layer 17. A gate insulating layer 12 and a gate electrode 13 are successively stacked in layers on part of the surface of the p-type silicon substrate 10, located between the drain electrode 11b and source electrode 11a. On the upper side of the source electrode 11a, a contact plug 18 is formed, penetrating through both the 1st and 2nd interlayer insulating layers 15 and 17. The contact plug 18 is formed by filling in via holes formed in the 1st and 2nd interlayer insulating layers 15 and 17 with, for example, tungsten (W) or polysilicon.

In the memory device 1, the selection FET member 100 is made up of the source electrode 11a, drain electrode 11b, gate insulating layer 12 and gate electrode 13 formed as described above. Note that wiring (not shown in the figure) for the gate electrode 12 and the metal wiring 16 is provided to connect them to a driving unit (not shown).

On the upper side of the contact plug 18 which extends to the top surface of the 2nd interlayer insulating layer 17, an underside electrode 19 is formed. The underside electrode 19 has a layered structure comprising: a conductive hydrogen barrier layer 19a having a function of preventing hydrogen diffusion; conductive oxygen barrier layers 19b and 19c, each having a function of preventing oxygen diffusion; and a conductive layer 19d. In addition, an insulating lateral-side barrier layer 20 having a function of preventing hydrogen diffusion is formed on the lateral side of the underside electrode 19 within the buried insulating layer 21. The underside electrode 19 and lateral-side barrier layer 20 are formed so as to have their top surfaces at substantially the same level as the surface of the buried insulating layer 21. Then, the underside electrode 19 is connected to the variable resistance layer 22.

The underside electrode 19 and upside electrode 24 sandwiching therebetween the variable resistance layer 22 in the thickness direction are formed so that the upside electrode 24 has a larger junction area with the variable resistance layer 22 than the underside electrode 19 does, as shown in FIG. 2. In the memory device 1, the variable resistance layer 22 and the underside and upside electrodes 19 and 24 make up the variable resistance member 101.

The memory device 1 of the present embodiment comprises the FET member 100 and variable resistance member 101 which are stacked one on top of the other, as has been described, and thereby has a small occupying area.

From among the components of the memory device 1, the underside electrode 19 has a layered structure comprising the hydrogen barrier layer 19a, oxygen barrier layers 19b and 19c, and conductive layer 19d, as described above. Of these, the hydrogen barrier layer 19a is made, for example, of titanium aluminum nitride (TiAlN), and has a thickness of approximately 40 nm to 100 nm. The oxygen barrier layer 19b is made, for example, of iridium (Ir), and is set approximately to 50 nm to 100 nm in thickness, while the oxygen barrier layer 19c being made, for example, of iridium dioxide (IrO₂) with a thickness of about 50 nm to 100 nm. The conductive layer 19d is made, for example, of platinum (Pt), and has a thickness set to around 50 nm to 100 nm. Note that the sequence for laying the hydrogen barrier layer 19a, oxygen barrier layers 19b and 19c, and conductive layer 19d, which make up the underside electrode 19, is not limited to that of the present embodiment. For instance, the hydrogen barrier layer 19a and the oxygen barrier layers 19b and 19c can be reversed, or the oxygen barrier layers 19b and 19c can be reversed.

The variable resistance layer 22 is made of a material having a perovskite structure, such as PCMO for example, and has a thickness of approximately 50 nm to 150 nm. The upside electrode 24 is made, for example, of platinum (Pt) with about 50 nm to 100 nm in thickness.

The lateral-side barrier layer 20 is made, for example, of aluminum oxide (Al₂O₃) with a thickness of 5 nm to 100 nm, and functions to prevent diffusion of oxygen and hydrogen.

Here, the junction area of the underside electrode 19 with the variable resistance layer 22 is, as described above, set smaller than the junction area of the upside electrode 24. Specifically speaking, the diameter of the underside electrode 19 in the direction along the surface of the substrate 10 is smaller than the diameters of the variable resistance layer 22 and the upside electrode 24 in the substrate's surface direction, and the rim portions of the variable resistance layer 22 and upside electrode 24 overhang the edge of the underside electrode 19.

The lateral side of the underside electrode 19—that is, the lower side of the overhanging portion of the variable resistance layer 22, is filled in by the buried insulating layer 21 which is an insulating hydrogen barrier made of silicon oxynitride (SiON) or silicon nitride (Si₃N₄). The buried insulating layer 21 electrically isolates, in the case where multiple memory cells are integrated, the underside electrode 19 from neighboring underside electrodes. The top surface of the buried insulating layer 21 is leveled to have substantially the same height as the surface of the underside electrode 19.

The variable resistance layer 22 and the upside electrode 24 are respectively formed by etching processes using the same mask, while the lateral-side barrier layer 20 being etched with a mask different from the one used for the upside electrode 24 and the variable resistance layer 22. Note that the buried insulating layer 21 may be formed by etching with the use of the same mask for the variable resistance layer 22 and the upside electrode 24.

In the memory device 1, the upside and lateral sides of the variable resistance layer 22 are covered by the hydrogen barrier layer 26, leaving no space therebetween. The lower side of the variable resistance layer 22 is covered by the buried insulating layer 21 functioning as a hydrogen barrier, together with the lateral-side barrier layer 20 and the hydrogen barrier layer 19a of the underside electrode 19, without leaving any space in between.

The lateral-side barrier layer 20 increases adhesion between the underside electrode 19 and the buried insulating layer 21, and thus plays a role of preventing gap formation therebetween. Note that the lateral-side barrier layer 20 and the hydrogen barrier layer 26 are, here, not provided to a region other than where the variable resistance member 101 is formed, for example, where the contact plug 18 connected to the source and drain electrodes 11a and 11b is formed.

### 1.2 Manufacturing Method for Memory Device 1

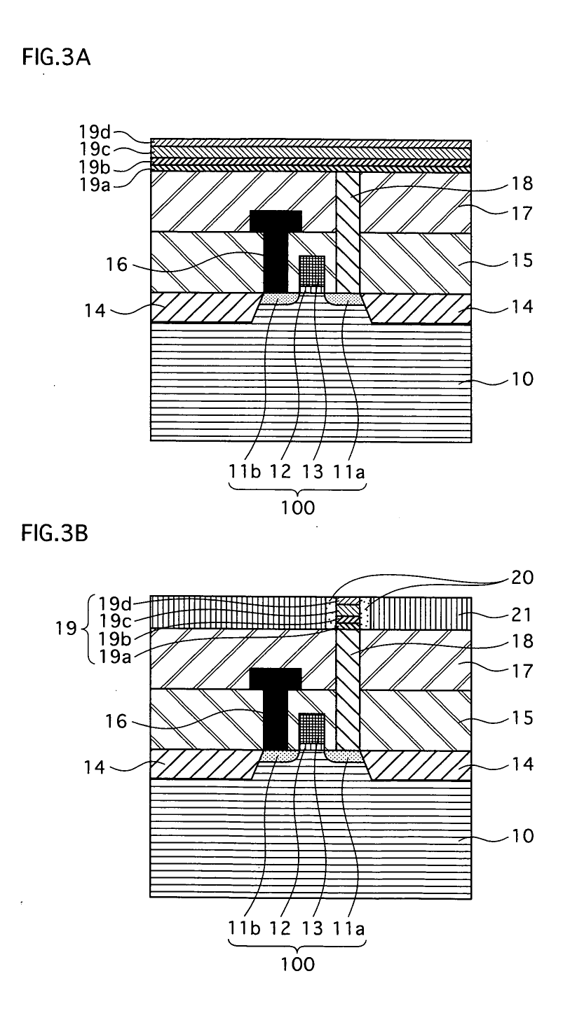

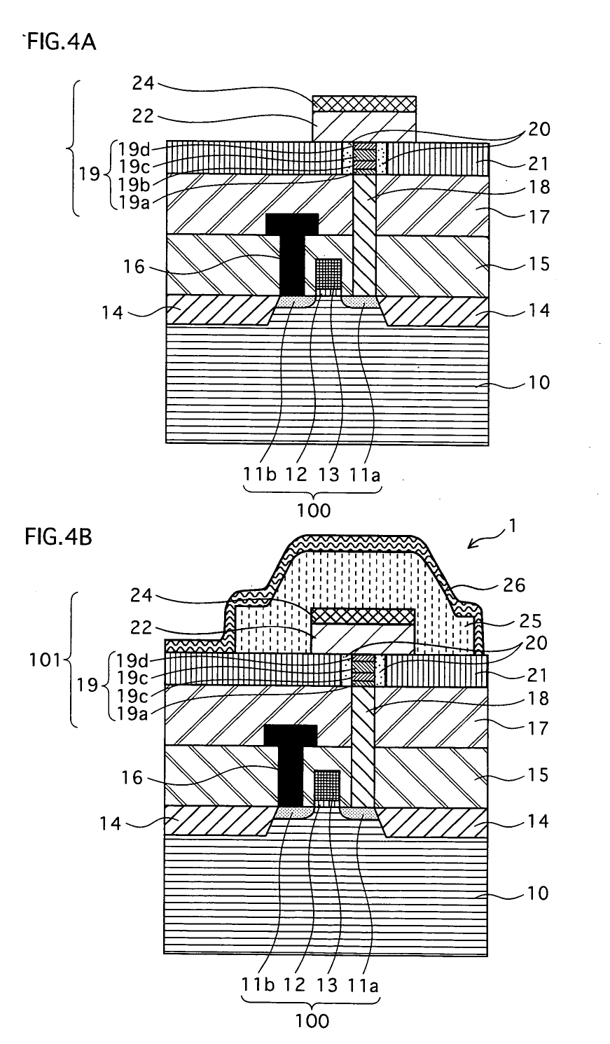

The following gives an account of the manufacturing method for the memory device 1 according to the present embodiment, with the aid of FIGS. 3A, 3B, 4A and 4B. Note that, although FIGS. 3A, 3B, 4A and 4B depict only part of the memory device 1—one cell which comprises a single variable resistance member 101 and a single FET member 100, the following description details a manufacturing method for a memory device having multiple cells.

First, as shown in FIG. 3A, the gate insulating layers 12 and gate electrodes 13 are successively laid on the surface of the p-type silicon substrate 10. Then, sections with n-type impurities are formed by, while the top surfaces of the gate electrodes 13 are masked, injecting impurities into the rest of the surface of the p-type silicon substrate 10, and thus the source and drain electrodes 11a and 11b are formed. Subsequently, by using CVD (chemical vapor deposition) method, silicon oxide is deposited over the entire surface of the p-type silicon substrate 10 including multiple FET members 100 formed thereon to thus form the 1st interlayer insulating layer 15.

After the top surface of the deposited 1st interlayer insulating layer 15 is planarized by, for example, chemical mechanical polishing (CMP), contact holes are formed in the 1st interlayer insulating layer 15, on the upper side of the drain electrode 11b of each FET member 100, by lithography and dry etching. Then, a conductive film made of tungsten or polysilicon is deposited so as to fill up each contact hole by CVD method. Then, an etch-back or a CMP operation is performed on the deposited conductive film so as to remove it from the surface of the 1st interlayer insulating layer 15, and thereby multiple contact plugs are formed.

Next, on the surface of the 1st interlayer insulating layer 15 bearing the multiple contact plugs, a conductive film made of polysilicon is deposited by, for example, CVD method. Then, by lithography and dry etching, patterning is performed on the deposited conductive film in a manner to include the contact plugs, and thereby multiple metal wirings 16 are formed.

Then, silicon oxide is deposited, by CVD, on the entire surface of the 1st interlayer insulating layer 15 bearing the multiple contact plugs, and herewith, the 2nd interlayer insulating layer 17 is formed. Following this, the top surface of the deposited 2nd interlayer insulating layer 17 is planarized by CMP, for example. Then, contact holes are formed in the 2nd interlayer insulating layer 17, on the upper side of the source electrode 11a of each FET member 100, by lithography and dry etching. Then, a conductive film made of tungsten (W) or polysilicon is deposited so as to fill up each contact hole by CVD method. Then, an etch-back or a CMP operation is performed on the deposited conductive film so as to remove it from the surface of the 2nd interlayer insulating layer 17, and thereby multiple contact plugs 18 are formed.

Subsequently, the underside electrode films are formed, using for instance a sputtering technique, by successively depositing the following layers: the hydrogen barrier layer 19a made of titanium aluminum nitride and having a function of preventing hydrogen diffusion; the oxygen barrier layer 19b made of iridium and having a function of preventing oxygen diffusion; the oxygen barrier layer 19c made of iridium dioxide and having a function of preventing oxygen diffusion; and the conductive layer 19d made of platinum.

Next, by lithography and dry etching, patterning is performed on the underside electrode films in a manner to include the contact plugs 18, and thereby the underside electrodes 19 are formed, as shown in FIG. 3B. Then, aluminum oxide is deposited, by sputtering or CVD, on the surface of the 2nd interlayer insulating layer 17 so as to cover the top surface and lateral side of each underside electrode 19, and thus the lateral-side barrier layers 20 each having a thickness of approximately 5 nm to 100 nm are formed. At this point—after the lateral-side barrier layers 20 are formed, it is desirable that the formed lateral-side barrier layers 20 be treated with heat in an oxidizing atmosphere so that aluminum oxide constituting the lateral-side barrier layers 20 is densified.

Subsequently, by using silane (SiH₄) as a basic ingredient and employing CVD technique in an atmosphere containing hydrogen, for instance, the buried insulating layer 21 made of silicon oxynitride or silicon nitride is formed with a thickness of about 400 nm to 600 nm so as to cover the surface of the 2nd interlayer insulating layer 17. Then, by using CMP, the buried insulating layer 21 and lateral-side barrier layers 20 are planarized until each underside electrode 19 is exposed, and thus, the surrounding area of each underside electrode 19 is filled in by the buried insulating layer 21. Accordingly, the top surfaces of the underside electrodes 19 have substantially the same height as the exposed surfaces of the buried insulating layer 21 and lateral-side barrier layers 20.

Then, as shown in FIG. 4A, PCMO is deposited, using pulse laser deposition (PLD) to form a variable resistance film. Here, the formation is carried out in, for example, the following conditions: a Pr—Ca—Mn target is irradiated for ten minutes with a KrF laser having a wavelength of 248 nm and a power of 550 mJ, while the substrate temperature and the oxygen pressure are set to 630° C. and 100 mTorr (≈1.33×10 Pa), respectively. Under such conditions, the variable resistance film having a thickness of 100 nm is formed on the surface of the buried insulating layer 21. The variable resistance film made of PCMO has a relative dielectric constant of 85, a resistivity in a low electric resistance state of 0.1 Ω·cm, and a resistivity in a high electric resistance state of 100 Ω·cm.

Subsequently, platinum (Pt) is deposited on the surface of the variable resistance film by sputtering so as to be about 50 nm to 100 nm thick, and thereby the upside electrode film is formed. Then, heat treatment in the presence of oxygen at a temperature of 600° C. to 800° C. is conducted in order to improve the crystal quality of a metal oxide constituting the variable resistance film. Next, a resist pattern (not shown) is formed on the surface of the upside electrode film by lithography, and dry etching is performed sequentially on the upside electrode film and the variable resistance film by using the formed resist pattern as a mask. Thereby, the upside electrodes 24 and the variable resistance layers 22 each having a configuration as shown in FIG. 4A are formed. Thus, the variable resistance members 101 is formed, each comprising: the underside electrode 19 to be electrically connected to the contact plug 18; the variable resistance layer 22; and the upside electrode 24.

As shown in FIG. 4B, by atmospheric pressure CVD, silicon oxide containing no hydrogen is deposited, with a thickness of about 20 nm to 200 nm, on the surface of the buried insulating layer 21 in a manner to cover where the variable resistance layers 22 are formed. Herewith, the interlayer insulating layer 25 is formed. Subsequently, by CVD or sputtering, aluminum oxide is deposited with a thickness of 5 nm to 100 nm to cover the interlayer insulating layer 25, and thereby the hydrogen barrier layer 26 is formed. As a result, in the lateral direction from each underside electrode 19, the hydrogen barrier layer 26 is in contact with the top surface of, in this case, the burried insulating loayer 21, leaving no space in between.

Thus, the memory device 1 according to the present embodiment is manufactured.

### 1.3 Advantageous Effects of Memory Device 1

In the memory device 1 of the present embodiment having the above structure, the hydrogen barrier layer 26 having a function of preventing hydrogen diffusion, the buried insulating layer 21, the lateral-side barrier layer 20, and the hydrogen barrier layer 19a of the underside electrode 19 are formed to enclose the surrounding region of the variable resistance layer 22 made of a metal oxide. A memory device having such a structure in which hydrogen-diffusion preventing components are formed in the surrounding region of the variable resistance layer 22 is capable of preventing the variable resistance layer 22 made of a metal oxide from being deoxidized by hydrogen during operations in the manufacturing processes where the memory device is placed in a deoxidizing atmosphere. As a result, the memory device 1 after the completion of the manufacture has the variable resistance member 101 exhibiting excellent switching performance.

In particular, the upper and lateral sides of the variable resistance layer 22 are covered by the hydrogen barrier layer 26 without leaving any space therebetween, while the lower side of the variable resistance layer 22 is covered by the hydrogen barriers (i.e. the buried insulating layer 21, the lateral-side barrier layer 20, and the hydrogen barrier layer 19a of the underside electrode 19) leaving no space in between. Furthermore, the hydrogen barrier layer 26 and the buried insulating layer 21 are joined to each other, and herewith, the variable resistance layer 22 is covered by the hydrogen barrier layers with no space left in between.

Additionally, since the hydrogen barrier layer 26 formed to cover the upper side of the variable resistance layer 22 is made of an insulating material, it is possible to prevent parasitic capacitance from being created, within the variable resistance member 101, between the hydrogen barrier layer 26 and the variable resistance layer 22. Alternatively, in the case where multiple variable resistance members 101 are integrated in close proximity to each other, cross talk between the members positioned next to each other can be prevented by the hydrogen barrier layer 26 covering the upper side of each variable resistance layer 22.

Since at least part of hydrogen barrier layers formed to cover the lower side of the variable resistance layer 22—that is, the hydrogen barrier layer 19a of the underside electrode 19—is made of a conductive material, not only can the memory device 1 of the present embodiment prevent hydrogen diffusion, but also it is capable of applying an electric potential to the variable resistance layer 22, via this conductive material of the hydrogen barrier layer 19a, from the lower side of the variable resistance layer 22.

Because having a structure in which the variable resistance layer 22 is partially in contact with the buried insulating layer 21 as well as with the lateral-side barrier layer 20, the memory device 1 also has the advantageous effect of simplifying the manufacturing processes.

The interlayer insulating layer 25 is inserted into a portion between the variable resistance layer 22 and the hydrogen barrier layer 26. Accordingly, as shown in FIG. 2, in the case where the variable resistance layer 22 is has difference in level on the surface thereof, it is possible to prevent causing, for example, a discontinuity in the hydrogen barrier layer 26 formed on the upper side of the variable resistance layer 22 due to the level difference. Besides, since the interlayer insulating layer 25 does not contain hydrogen, the chance of hydrogen diffusion into the variable resistance layer 22 can be avoided.

Of the two electrodes 19 and 24 respectively positioned on the upper and lower side of the variable resistance layer 22, at least the underside electrode 19 includes a layer having a function of preventing hydrogen diffusion, i.e. the hydrogen barrier layer 19a. Therefore, the memory device 1 is capable of preventing hydrogen diffusion through the electrodes, which in turn prevents the variable resistance layer 22 from being deoxidized in a reliable fashion.

The lateral-side barrier layer 20, made of a different material from one constituting the hydrogen barrier layer 19a, is formed in contact with both sides of the hydrogen barrier layer 19a of the underside electrode 19, and accordingly the memory device 1 is capable of preventing the deoxidation of the variable resistance layer 22 in a more definitive manner. Since the underside electrode 19 joined to the lower side of the variable resistance layer 22 includes the hydrogen barrier layer 19a having a function of preventing hydrogen diffusion and the oxygen barrier layers 19b and 19c each having a function of preventing oxygen diffusion, not only can the memory device 1 prevent the variable resistance layer 22 from being deoxidized in a reliable fashion, but also it is capable of preventing the contact plug 18 and FET member 100 formed to the lower side of the underside electrode 19 from being oxidized. In addition, the memory device 1 is also able to prevent the oxygen barrier layers 19b and 19c of the underside electrode 19 from being deoxidized by hydrogen, which results in preventing degradation in their oxygen barrier performance.

Additionally, in the memory device 1, the paired underside and upside electrodes 19 and 24 are placed opposite to each other, sandwiching the variable resistance layer 22 in the thickness direction. Herewith, the memory device 1 is capable of readily changing the electric resistance state of the variable resistance layer 22 by applying voltage to the variable resistance layer 22 using the pair of electrodes 19 and 24.

In a semiconductor apparatus having the memory device 1 of the present embodiment, the connection between the contact plug 18 and the underside electrode in the variable resistance member 101 achieves: the variable resistance member 101 having the variable resistance layer 22 resistant to deoxidation even when the memory device 1 is exposed to a deoxidizing atmosphere; and the contact plug 18 and the FET member 100 less susceptible to oxidation.

### 1.4 Examination on Advantageous Effects of Memory Device 1

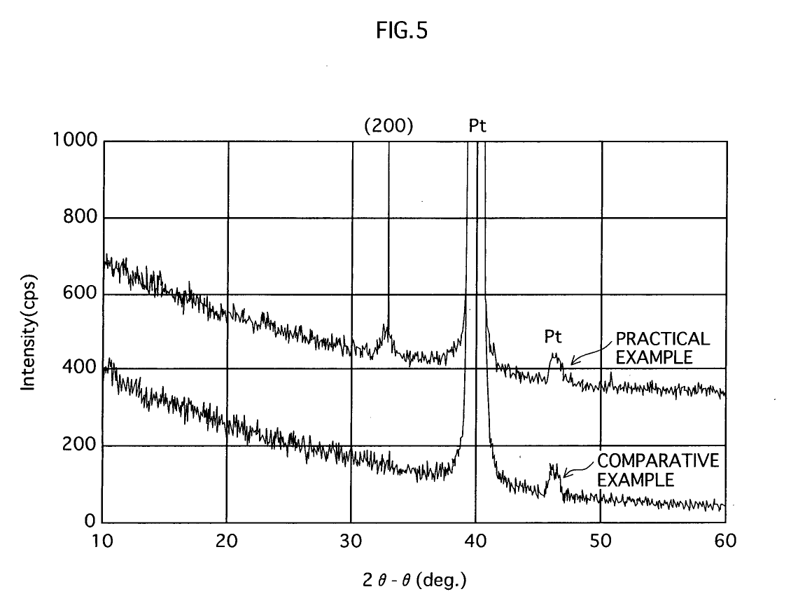

The following describes, with the aid of FIG. 5, the assessment carried out for the variable resistance member 101 of the memory device 1 according to the present embodiment in terms of the resistance to deoxidation. FIG. 5 shows the X-ray diffraction profiles of the following two types of memory devices, obtained after a 10-minute heat treatment at 400° C. in 100% hydrogen (i.e. hydrogen annealing): a practical example memory device having the same structure as the memory device 1 in which the variable resistance layer is covered by hydrogen barrier layers; and a comparative example memory device in which the variable resistance layer is not covered by hydrogen barrier layers.

Regarding the comparative example memory device, a diffraction peak corresponding to the crystal structure of the variable resistance layer made of PCMO was not observed, as shown in FIG. 5. On the other hand, since the practical example memory device has a structure in which the surrounding region of the variable resistance layer is enclosed by hydrogen-diffusion preventing layers, a clear diffraction peak corresponding to the crystal structure of the variable resistance layer was observed even after the hydrogen annealing. It can be seen that, as to the practical example memory device, the variable resistance layer is free from a deoxidation reaction and the regularity of the crystal structure was not lost.

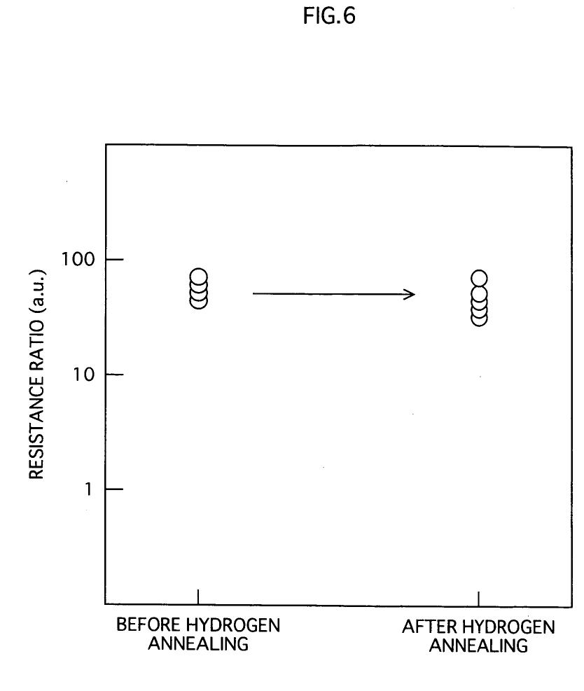

The following gives an account of results obtained from a comparison of an electric characteristic between a semiconductor apparatus having the practical example memory device and a semiconductor apparatus having the comparative example memory device, with the aid of FIG. 6. FIG. 6 shows the resistance ratios of the variable resistance member in a high electric resistance state to that in a low electric resistance state, obtained before and after the above hydrogen annealing was performed on the practical example memory device.

As shown in FIG. 6, the variable resistance member of the practical example memory device hardly has change in the electric resistance characteristic even after hydrogen annealing, and deoxidation by hydrogen is well prevented. Thus, the practical example memory device and a semiconductor apparatus having the practical example memory device are capable of achieving a significant improvement in the electric characteristic.

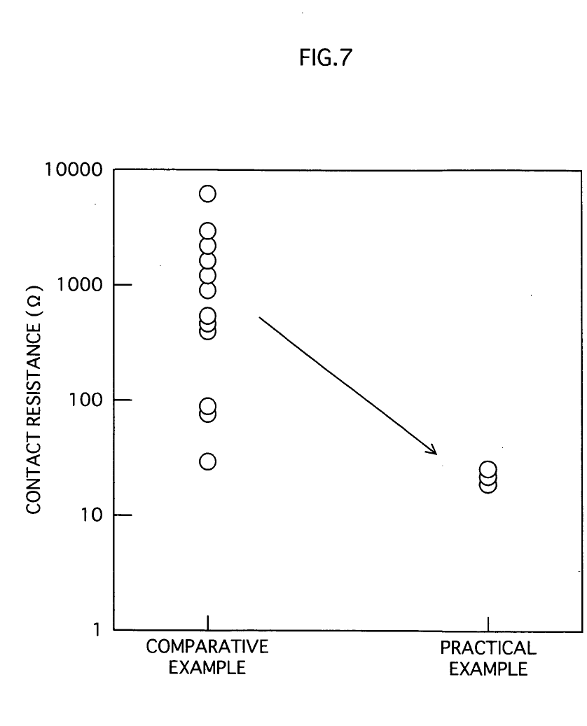

Next is described, with the aid of FIG. 7, results obtained from the assessment of contact resistance between the contact plug and the underside electrode in relation to the practical example and comparative example memory devices. FIG. 7 shows measurements of the wafer's in-plane contact resistance of the practical and comparative example memory devices.

As shown in FIG. 7, the semiconductor apparatus having the comparative example memory device has a contact resistance largely varying between 45Ωand 7000Ω. This is attributed to that: iridium dioxide constituting the conductive oxides forming an oxygen barrier in the underside electrode is deoxidized by hydrogen; and oxygen diffuses inside the underside electrode, and thereby, the surface of the contact plug is oxidized during high-temperature oxygen annealing, which is required to crystallize high dielectric and ferroelectric materials. As a result, the oxygen barrier performance of the underside electrode of the comparative example memory device undergoes degradation.

On the other hand, as shown in FIG. 7, the semiconductor apparatus having the practical example memory device has a wafer's in-plane contact resistance varying in a significantly narrow range of 25Ωto 35Ω, achieving a reduction in the electric resistance. This is, as described above, because the underside electrode of the practical example memory device has a layered structure comprising a hydrogen barrier layer and oxygen barrier layers, and herewith, the oxygen diffusion inside the underside electrode is prevented during the high-temperature oxygen annealing required to crystallize high dielectric and ferroelectric materials.

### 2. Embodiment 2

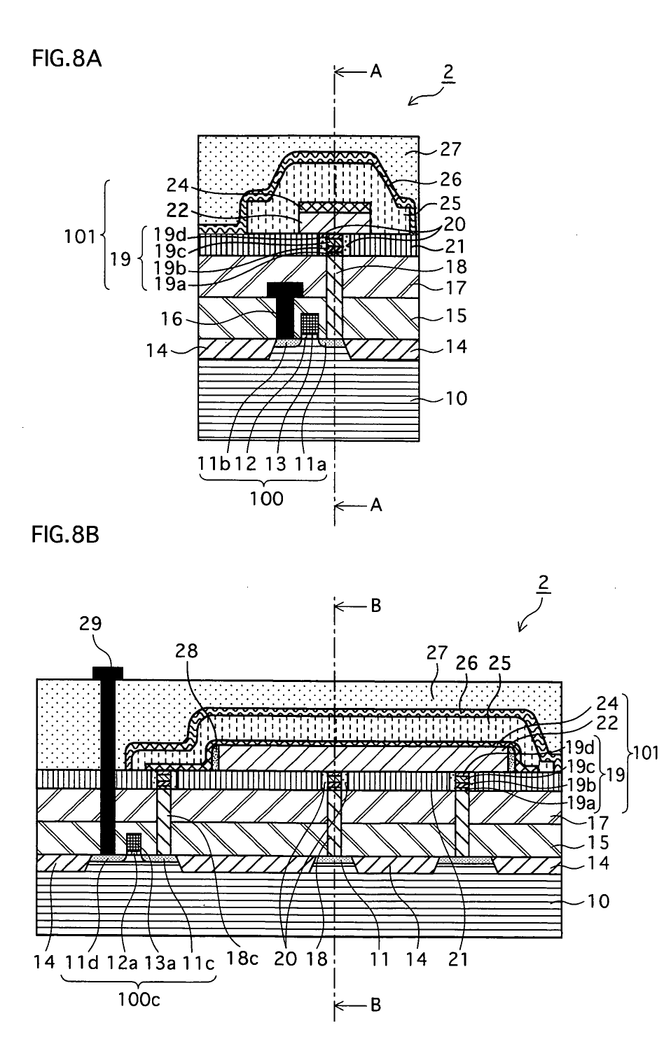

A memory device 2 of a semiconductor according to Embodiment 2 is described next with the reference to FIGS. 8A and 8B. Both figures are cross sections of the memory device 2 according to the present embodiment, with FIG. 8A showing a cross section of the memory device 2 along the line B-B (FIG. 8B) while FIG. 8B showing a cross section of the memory device 2 along the line A-A (FIG. 8A). FIGS. 8A and 8B illustrate: two memory cells being integrated, where each cell comprises a single variable resistance member 101 and a single FET member 100; and one memory-cell-plate transistor device 100c for supplying an electric potential to the upside electrodes of these two cells. However, the memory device 2 may have only one memory cell, or may have more than two memory cells.

As shown in FIG. 8A, the memory device 2 of the present embodiment further includes an insulating layer 27 made of silicon oxide and formed above the interlayer insulating layer 25, in addition to the components of the above memory device 1 according to Embodiment 1.

In addition, the memory device 2 has two variable resistance members 101 formed next to each other, and the variable resistance layer 22 and the upside electrode 24 serve as shared components of these two variable resistance members 101, as shown in FIG. 8B. Between the upside electrode 24 and the lateral side of the variable resistance layer 22, an insulating layer 28 made of silicon oxide is also formed. Then, the insulating hydrogen barrier layer 26 is formed to cover the variable resistance layer 22 and upside electrode 24.

The memory device 2 has the memory-cell-plate transistor device 100c comprising a source electrode 11c, a drain electrode 11d, a gate insulating layer 12a and a gate electrode 13a. The drain electrode 11d in the memory-cell-plate transistor device 100c is electrically connected to the upside electrode 24 via a contact plug 18c and the underside electrode 19.

Also, connected to the drain electrode 11d is a metal wiring 29 serving as a plate wire. Here, the metal wire 29 is formed without penetrating through the hydrogen barrier layer 26.

As to the memory device 2 according to the present embodiment, in any cross section including the variable resistance layer 22, the surrounding region of the variable resistance layer 22 is completely enclosed by the hydrogen barriers (the hydrogen barrier layer 26, the buried insulating layer 21, the lateral-side barrier layer 20, and the hydrogen barrier layer 19a of the underside electrode 19). Herewith, the memory device 2 achieves, in addition to the advantageous effects of the memory device 1 according to Embodiment 1 above, prevention of hydrogen diffusion into the variable resistance layer 22 made of a metal oxide from all directions. Thus, even when being exposed to a deoxidizing atmosphere, the memory device 2 is capable of preventing the variable resistance layer 22 from being deoxidized in a reliable manner.

### 3. Embodiment 3

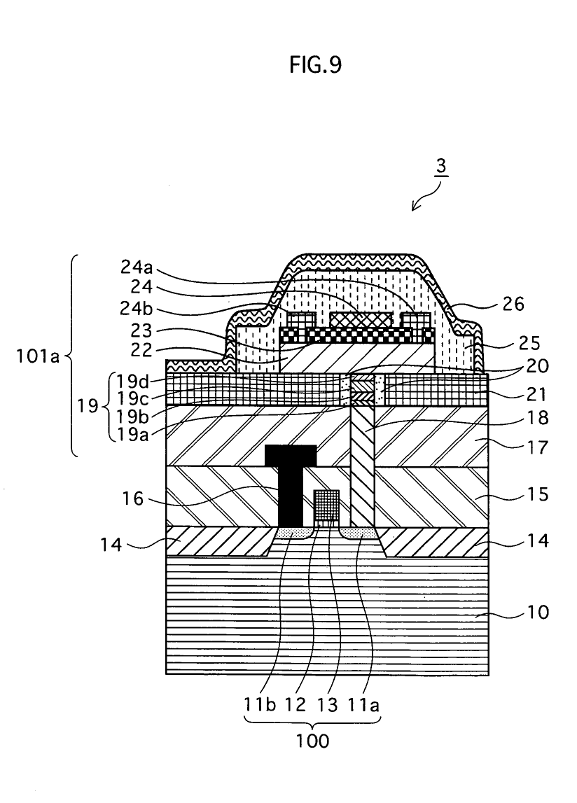

A memory device 3 of a semiconductor apparatus according to Embodiment 3 is described next with reference to FIG. 9. FIG. 9 is a cross section of relevant parts showing a structure of the memory device 3 according to the present embodiment. Note that, although FIG. 9 depicts one variable resistance member 101a and one FET member 100, the memory device 3 may have a structure where multiple memory cells, each of which comprises a single variable resistance member 101a and a single FET member 100, are integrated.

As shown in FIG. 9, the memory device 3 according to the present embodiment has a structure in which a variable resistance member (variable resistance switching unit) 101a and the selection FET member 100 are integrated. The following describes a difference of the variable resistance member 101a from the variable resistance member 101 according to Embodiment 1 above.

In the variable resistance member 101 of Embodiment 1, the same paired electrodes 19 and 24 for controlling the electric resistance state of the variable resistance layer 22 also operate as an electrode pair for detecting the electric resistance state of the variable resistance layer 22. In the variable resistance member 101a of the memory device 3 according to the present embodiment, on the other hand, detecting electrodes 24a and 24b for detecting the resistance state of the variable resistance layer 22 are provided on the surface of the variable resistance layer 22, aside from the underside and upside electrodes 19 and 24. Thus, by providing the detecting electrodes 24a and 24b, the memory device 3 of the present embodiment has an advantage of separating the wiring for controlling and detecting the electric resistance state of the variable resistance layer 22, on top of the advantageous effects of the memory device 1 according to Embodiment 1 above. Accordingly, the memory device 3 of the present embodiment is less likely to face restrictions on the circuit structure, and therefore offers high flexibility in the design of an electronic circuit.

In addition, in the memory device 3, a high dielectric constant layer 23 is inserted between the variable resistance layer 22 and the upside electrode 24. Herewith, the memory device 3 is capable, when voltage is applied between the control electrode pair 19 and 24 in order to control the electric resistance state of the variable resistance layer 22, of reducing a through current flowing between the electrode pair 19 and 24, which leads to a decrease in the power consumption. Here, the high dielectric constant layer 23 is made, for example, of SrTiO₃ (referred to hereinafter as “ST”) having a perovskite structure, and is formed to be 50 nm to 150 nm in thickness, which is substantially equivalent to the thickness of the variable resistance layer 22.

The high dielectric constant layer 23 is formed by depositing ST, for instance, by sol-gel process and then sintering the result at 650° C. The high dielectric constant layer 23 has a relative dielectric constant of 100 and a leakage current of 1 nA/cm² or less. The variable resistance layer 22 has a relative dielectric constant of 85, a resistivity in a low electric resistance state of 0.1 Ω·cm, and a resistivity in a high electric resistance state of 100 Ω·cm. On the other hand, being sintered at 650° C., the high dielectric constant layer 23 has a relative dielectric constant of 100 and a resistivity of 10⁴ Ω·cm. That is, in the memory device 3, the dielectric constant of the high dielectric constant layer 23 is set larger than that of the variable resistance layer 22. This enables an improvement in the concentration of an electric field on the variable resistance layer 22. Regarding the dielectric constant of the high dielectric constant layer 23, it is acceptable if the value is at least −10% of the dielectric constant of the variable resistance layer 22 in a high electric resistance state.

The resistivity of the high electric constant layer 23 is equal to or greater than that of the variable resistance layer 22 in a high electric resistance state, which achieves a decrease in the leakage current when the variable resistance layer 22 is in a high electric resistance state. Because the high dielectric constant layer 23 is made of ST, which is a material having a perovskite structure, its lattice mismatch with the variable resistance layer 22 made of PCMO having the same structure—a perovskite structure, can be avoided, which in turn prevents stress exerted on the variable resistance layer 22. Thus, in this point also, the memory device 3 of the present embodiment has an excellent structure for preventing degradation in the characteristics of the variable resistance layer 22.

Note that, although the memory device 3 of the present embodiment takes a structure in which the high dielectric constant layer 23 is interposed between the variable resistance layer 22 and the upside electrode 24, a structure may instead be adopted in which the high dielectric constant layer 23 is interposed between the underside electrode 19 and the variable resistance layer 22. Further alternatively, the high dielectric constant layer 23 may be interposed between the variable resistance layer 22 and both the underside and upside electrodes 19 and 24.

Although the electrodes 19, 24, 24a and 24b in the memory device 3 according to the present embodiment are arranged in the manner shown in FIG. 9, as a matter of course, the memory device 3 can adopt a positioning arrangement other than this. For instance, as a modification, the electrodes 24a and 24b can be placed on the lower side of the variable resistance layer 22, or the electrodes 24a and 24b may be respectively placed on the lower and upper side of the variable resistance layer 22. Alternatively, the underside electrode 19 or the upside electrode 24 may take up the function of either one of the electrodes 24a and 24b, serving as a shared electrode. Furthermore, another electrode may be positioned on the lower or the upper side of the variable resistance layer 22.

### 4. Additional Particulars

In Embodiments 1 to 3 above, examples are shown in order to illustrate structural and functional features of the variable resistance devices according to the present invention; however, the present invention is not limited to these. For example, Embodiments 1 to 3 describe the cases in which the variable resistance members 101 and 101a are applied to semiconductor memory apparatuses, however, they can be applied to, for example, programmable logic circuits or analog circuits.

Although Embodiment 1 to 3 above use PCMO to form the variable resistance layer 22, other CMR materials and high-temperature superconductive materials may be used instead. Specifically speaking, materials expressed in a chemical composition formula of A_{X}A′₍₁₋ₓ₎B_{y}O_{z} can be used for the variable resistance layer 22. Here, A, A′, B, X, Y and Z in the chemical composition formula are defined as follows:
A: at least one element selected from the group consisting of La, Ce, Bi, Pr, Nd, Pm, Sm, Y, Sc, Yb, Lu and Gd;
A′: at least one element selected from the group consisting of Mg, Ca, Sr, Ba, Pb, Zn and Cd;
B: at least one element selected from the group consisting of Mn, Ce, V, Fe, Co, Nb, Ta, Cr, Mo, W, Zr, Hf and Ni;
X: 0≦X≦1;
Y: 0≦Y≦2; and
Z: 1≦Z≦7.

The magnitude relation in terms of the connection sizes of the upside and underside electrodes 19, 24, 24a and 24b to the variable resistance layer 22 can be changed from one shown in Embodiments 1 to 3 above. The upside electrode 24 may have a smaller junction area with the variable resistance layer 22 than the underside electrode 19 does.

Although the present invention has been fully described by way of examples with reference to the accompanying drawings, it is to be noted that various changes and modifications will be apparent to those skilled in the art. Therefore, unless such changes and modifications depart from the scope of the present invention, they should be constructed as being included therein.

What is claimed is:

1. A variable resistance device comprising:
a variable resistance layer made of a metal oxide and causing changes in electric resistance thereof in accordance with control conditions; and
a hydrogen-diffusion preventing layer which surrounds at least part of the variable resistance layer and prevents hydrogen from diffusing into the variable resistance layer.

2. The variable resistance device of claim 1, wherein
the hydrogen-diffusion preventing layer surrounds a whole of the variable resistance layer.

3. The variable resistance device of claim 1, wherein
the hydrogen-diffusion preventing layer includes a 1st diffusion preventing component and a 2nd diffusion preventing component which are disposed across the variable resistance layer in a thickness direction of the variable resistance layer, and
the 1st and 2nd diffusion preventing components are made of different materials.

4. The variable resistance device of claim 3, wherein
the 1st diffusion preventing component is made of an insulating material.

5. The variable resistance device of claim 3, wherein
the 1st diffusion preventing component is made of an insulating material including at least one compound selected from the group consisting of silicon oxide, silicon oxynitride, silicon nitride, aluminum oxide, titanium aluminum oxide, and tantalum aluminum oxide.

6. The variable resistance device of claim 3, wherein
the 2nd diffusion preventing component is made of a conductive material.

7. The variable resistance device of claim 6, wherein
a plurality of electrodes having conductive properties are connected to the variable resistance layer, and
at least one of the plurality of electrodes functions as the 2nd diffusion preventing component.

8. The variable resistance device of claim 7, wherein
a high dielectric constant layer is inserted between the variable resistance layer and the at least one of the plurality of electrodes.

9. The variable resistance device of claim 8, wherein
the high dielectric constant layer is made of a material having a perovskite structure.

10. The variable resistance device of claim 7, wherein
within the at least one of the plurality of electrodes, a lateral side intersecting a plane connected to the variable resistance layer is covered by a lateral-side hydrogen-diffusion preventing layer which is made of a different material from the at least one of the plurality of electrodes and has a function of preventing hydrogen diffusion.

11. The variable resistance device of claim 7, wherein
the at least one of the plurality of electrodes has a layered structure in which a hydrogen-diffusion-preventing component layer for preventing diffusion of hydrogen and an oxygen-diffusion-preventing component layer for preventing diffusion of oxygen are stacked one on top of the other.

12. The variable resistance device of claim 11, wherein
the hydrogen-diffusion-preventing component layer includes at least one compound selected from the group consisting of titanium nitride, titanium aluminum nitride, titanium aluminum, titanium nitride silicide, tantalum nitride, tantalum nitride silicide, tantalum aluminum nitride, and tantalum aluminum.

13. The variable resistance device of claim 11, wherein
the oxygen-diffusion-preventing component layer includes at least one of (i) iridium oxide, (ii) a layered structure in which layers of iridium oxide and iridium are successively stacked in a stated order from a side closest to the variable resistance layer, (iii) ruthenium oxide, and (iv) a layered structure in which layers of ruthenium oxide and ruthenium are successively stacked in a stated order from the side closest to the variable resistance layer.

14. The variable resistance device of claim 1, wherein
part of the variable resistance layer is directly joined to part of the hydrogen-diffusion preventing layer.

15. The variable resistance device of claim 1, wherein
an insulating layer is inserted into a part between the variable resistance layer and the hydrogen-diffusion preventing layer.

16. The variable resistance device of claim 15, wherein
the insulating layer contains no hydrogen.

17. The variable resistance device of claim 1, wherein
the hydrogen-diffusion preventing layer includes at least one of a plurality of elements constituting the variable resistance layer.

18. The variable resistance device of claim 1, wherein
the hydrogen-diffusion preventing layer includes a magnetic element.

19. The variable resistance device of claim 1, wherein
the variable resistance layer is made of a material having a perovskite structure.

20. A semiconductor apparatus comprising a variable
resistance device, wherein the variable resistance device includes:
a variable resistance layer made of a metal oxide and causing changes in electric resistance thereof in accordance with control conditions; and
a hydrogen-diffusion preventing layer which surrounds at least part of the variable resistance layer and prevents hydrogen from diffusing into the variable resistance layer.
